(19) United States
(12) Patent Application Publication
(10) Pub. No.: US 2002/0141150 A1
(43) Pub. Date: Oct. 3, 2002

(54) THERMALLY CONDUCTIVE INLAY MAT FOR ELECTRICAL AND ELECTRONIC APPLIANCES

(76) Inventors: ANDREAS HUBER, MAISACH (DE); FRANZ FORSTER, KIRCHSEEON (DE); PETER NIEDERMEIER, MUENCHEN (DE); WALTER LIMMER, MUENCHEN (DE)

Correspondence Address: CARLO S BESSONE, OSRAM-SYLVANIA INC, 100 ENDICOTT STREET, DANVERS, MA, 01923

(21) Appl. No.: 09/383,210

(22) Filed: Aug. 26, 1999

(30) Foreign Application Priority Data
Sep. 9, 1998 (DE) 19841037.9
Sep. 24, 1998 (DE) 29817185.6

(51) Int. Cl. G06F 1/20; H05K 7/20

(52) U.S. Cl. 361/687; 361/711; 361/720

(57) ABSTRACT

An electrical appliance, in order to dissipate the heat appertaining to the power loss in its housing, has a mat (3) between the circuit board which supports the electronic components and the adjoining wall part.

### TECHNICAL FIELD

The invention relates to a thermally conductive inlay mat for electrical and electronic appliances in accordance with the preamble of claim 1. These appliances are in particular operating equipment for high-pressure discharge lamps, but also for incandescent halogen lamps and low-pressure discharge lamps. Further applications are audio and video appliances, dimmers and various power electronics devices, for example for motor/engine control. A characteristic feature is the relatively high power loss which occurs in the appliances as a result of high currents of the approximate order of magnitude of from less than 1 A to more than 50 A.

The power loss which occurs during operation of electronic and electrical appliances is converted into heat. This heat is produced in the interior of the appliance and has to be dissipated outward. Particularly when the appliances have closed housings, the heat loss has to be transmitted as effectively as possible, by heat conduction, from the heat source inside the appliance to the appliance wall and, from there, has to be dissipated to the environment. The heat source is one, or generally more, electrical or in particular electronic components, the latter in particular being extremely sensitive to overheating. The components are generally mounted on a circuit board. For many surface-mounted components of different heights, it is not always possible to ensure that they are in direct contact with a heat sink or a cooling lug.

### PRIOR ART

Hitherto, the following principle has been used to prevent a buildup of heat in electrical appliances: at least part of the appliances is embedded in a potting compound with good thermal conductivity. For example, the document EP-A 645 944 has disclosed an operating device for electric lamps in which the heat is dissipated through a thermally conductive potting compound. This compound transmits the heat to the housing walls, where it can be dissipated to the environment.

### SUMMARY OF THE INVENTION

The object of the present invention is to provide a thermally conductive inlay mat for electrical and electronic appliances in accordance with the preamble of claim 1, which can be used to dissipate the heat in these appliances in a particularly simple manner.

This object is achieved by means of the distinguishing features of claim 1. Particularly advantageous refinements are given in the dependent claims.

The thermally conductive inlay mat for electrical and electronic appliances has a base body of simple, sheet-like geometry, an underside being intended to be in contact with the outer wall of the appliance and a top side of the base body being intended to be in contact with the heat source inside the appliance. Preferably, the top side is provided with a height-compensating structure, while the underside may be smooth. A suitable material is a material with a low Shore hardness of at most 15. In a particularly preferred embodiment, modified hydrocarbon resin or silicone composite sheet is used.

The introduction of the newly developed mat allows the heat loss in such appliances to be transmitted particularly reliably and effectively from the heat source to an external wall of the appliance. By way of example, the heat source is an electronic component on a circuit board. When the mat (minimum thickness 1 mm) has been laid between circuit board and appliance wall, it is possible to dissipate the heat loss via the underside of the circuit board and to transmit this heat to the appliance wall, in particular a base plate, without having to take any account of the position of electronic components, for example SMD components, on the underside of the circuit board. Advantageously, the mat has a special structure on its surface facing toward the electrical or electronic components, which structure makes it possible to compensate for the different heights of various components. Raised lamellae which are arranged parallel to one another are, for example, eminently suitable. Typically, a mat of this nature makes it possible to compensate for approx. 3 mm without its heat-dissipating function being impaired. This inlay mat preferably comprises electrically insulating material, such as plastic or ceramic, in particular synthetic resin, such as modified hydrocarbon resin, for example Guronic-FR produced by Paul Jordan, or silicone composite sheets, for example KU-TKC or KU-TKM produced by Kunze Folien, which are filled with ceramic in order to increase the thermal conductivity still further. Mats made from homogeneous synthetic resin are deformable, flexible and have a soft and sticky consistency, and may exhibit a high level of electrical insulation. The said materials can be cast in any desired shapes and are therefore readily able to meet the requirements imposed with regard to shape.

This mat is of simple geometric shape (e.g. rectangular) and its thickness is expediently dimensioned suitably for the distance between heat source and appliance wall, for example between circuit board and base plate of an appliance. A thickness of from 1 to 10 mm is well suited in practice. In particular, synthetic resin is a soft and yielding material. A height-compensating structure on at least one surface allows good thermal contact to be achieved even for different heights of various electronic components.

Advantageously, the mat has raised lamellae on at least the top side, which faces toward the circuit board, which lamellae leave sufficient space to accommodate projections on the electronic components. A rectangular or trapezoidal cross section of the lamellae is eminently suitable. The base width of and the distance between the lamellae should be of approximately the same order of magnitude (factor 1:2 to 2:1). The distance between and the height of the lamellae is preferably between 1 and 8 mm. These dimensions ensure good thermal contact with conventional electronic components, which are of approximately the same size.

Particular advantages compared to a potting compound are that it is possible for the appliance to be opened again, that the mechanical load caused by different coefficients of thermal expansion is lower, and that less material is consumed. The thickness of the inlay mat is dimensioned in such a way that the inlay mat is in as good contact with the heat source as possible (the heat source is in particular the underside of the circuit board).

Further advantages consist in the fact that the improved dissipation of heat in the appliances fitted with the inlay mat extends the possible applications of such appliances to environments which are subjected to high thermal loads. This applies, for example, to operating devices of electric lamps, which are then suitable even for thermally disadvantageous luminaire structures. Moreover, appliances of this nature are more suitable for recycling and are better able to satisfy the conditions of electronic scrap regulations. Furthermore, it is now possible to rework these appliances during manufacture.

It is also possible to use a plurality of inlay mats in one electronic appliance. This is advisable, for example, if a plurality of electronic circuit boards are used in the appliance with different orientations.

### FIGURES

The invention will be explained in more detail below with reference to an exemplary embodiment. In the drawings:

FIG. 1 shows an inlay mat in plan view (FIG. 1a), in longitudinal section (FIG. 1b) and in cross section (FIG. 1c)

FIG. 2 shows an operating device for a discharge lamp in side view and partially in section

FIG. 3 shows the operating device from FIG. 2 with the top part removed.

### DESCRIPTION OF THE DRAWINGS

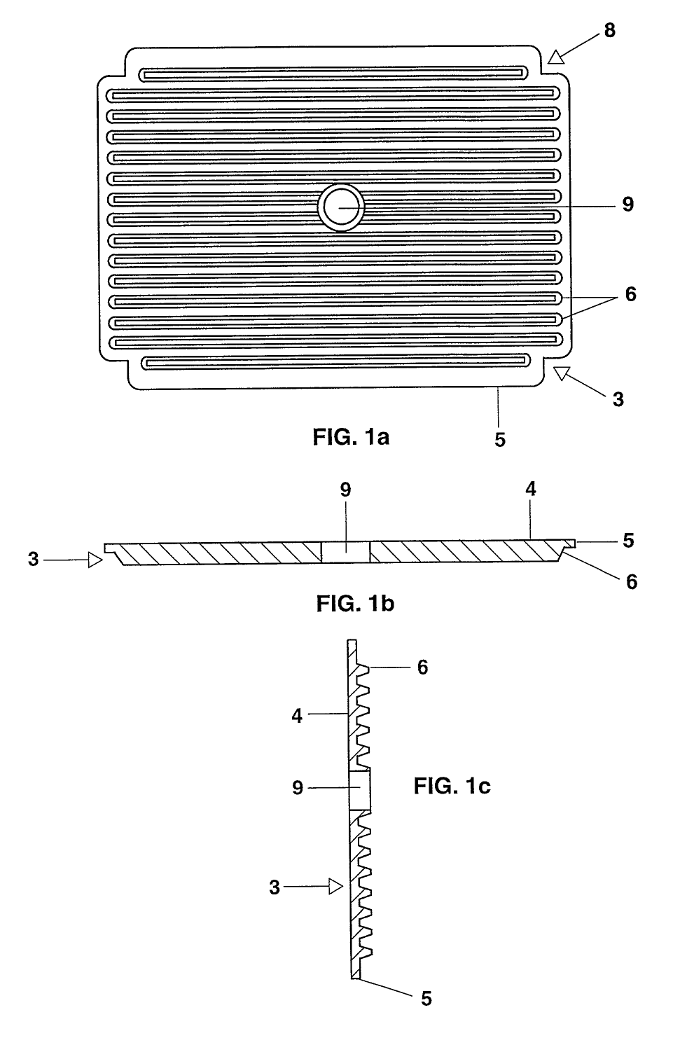

FIG. 1 shows an approximately rectangular inlay mat 3 with a length of 11 cm, a width of 7.5 cm and a total thickness of 4.5 mm. Mutually parallel, longitudinally oriented lamellae 6 of rectangular cross section with a height of 2.5 mm and a width of approximately 1 mm are arranged on the top side, which faces toward the heat source, on a base body 5 with a thickness of 2 mm. The underside 4 is smooth and thus provides optimum thermal contact with the appliance wall. The lamellae 6 are spaced apart by approximately 3 mm in each case. The overall result is a structure with a sawtooth or meandering cross section (FIG. 1c) . The mat 3 has indents 8 at its four corners and also a central hole 9, which together make it easier to hold and align the mat 3 in the appliance or form recesses for attachment means. The mat comprises modified hydrocarbon resin which makes the mat sticky at its surface. The Shore A hardness is 10. The mat therefore has good adhesion to the base plate and very good thermal contact with the circuit board.

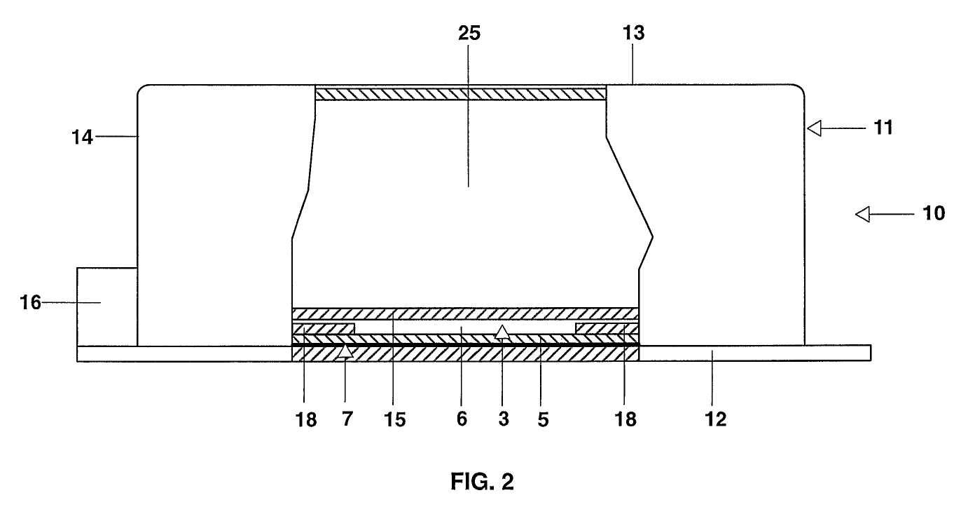

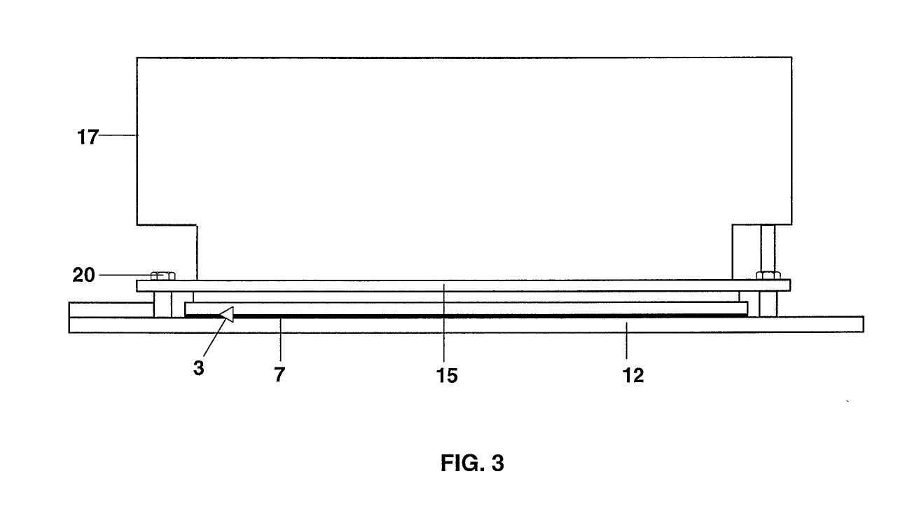

An additional film 7 (cf. FIGS. 2 and 3) made from plastic (Hostafen), which is arranged between mat and base plate, makes it possible to ensure electrical insulation between circuit board and base part even in the unlikely event of a component penetrating through the mat or of current being fed through the mat to the wall of the appliance. If the thickness of the film 7 is 0.1 mm, the result, in the installed state, is therefore an overall thickness of 4.6 mm.

FIG. 2 shows an operating device for a high-pressure discharge lamp as an exemplary embodiment of an electronic appliance. For this device, an electronic ballast 10 is used with a housing made from plastic and metal. This housing is divided into a metal base plate 12 made from aluminum and a top part 11 made from plastic, comprising a cover 13 with attached side walls 14. A horizontal electronic circuit board 15 (shaded), which is surrounded by the housing and on which the electronic components (not shown) are mounted, is attached to the base plate 12 by means of screws 20. In addition, an on-edge circuit board (not visible) is mounted in the interior 25 of the housing. An inlay mat 3 with good thermal conductivity is laid between circuit board 15 and base plate 12. On one of the side walls, there is a connection part 16 which is screwed to the base plate 12 and is used for electrically connecting the lamp to the operating device and to supply the operating device with voltage.

After the mounting circuit board 15, including the electronic and electrical components which are arranged thereon, has been attached to the base plate 12, the top part 11 is fitted onto the base plate 12 and is locked to the circuit board 15 by means of a snap-action connection 18. The dimensions of the mat 3 are slightly smaller than those of the circuit board 15, so that there is no need to provide a special recess on the mat 3 for the snap-action mechanism which is located at the outer edge of the circuit board.

FIG. 3 shows the electronic ballast without the surrounding cover or side wall. In addition to the horizontal circuit board 15, the electronic ballast also has a circuit board 17 which is positioned on edge. The distance between the horizontal circuit board 15 and the base plate 12 is 4.5 mm. In this way, it is ensured that the inlay mat 3 is always in thermally conductive contact both with the circuit board 15 and with the base plate 12.

The geometry of the mat is adapted to the geometry of the base plate. A further mat of this nature may also be inserted between the on-edge circuit board 17 and the adjoining side wall.

A comparison with an identical operating device which, however, was provided with conventional potting compound revealed a considerable improvement in the maximum permissible ambient temperature for the luminaire of 15° C. While previous luminaires were only able to tolerate an ambient temperature of 25° C., they are now able to withstand a load of up to 40° C.

1. A thermally conductive inlay mat (3) for electrical and electronic appliances, having a base body (5) of simple sheet-like geometry, an underside (4) of the base body being intended to be in contact with the outer wall of the appliance and a top side of the base body being intended to be in contact with the heat source inside the appliance.

2. The inlay mat as claimed in claim 1, wherein the mat (3) comprises modified hydrocarbon resin or a silicone composite sheet.

3. The inlay mat as claimed in claim 1, wherein the mat (3) comprises electrically insulating material, in particular homogeneously comprises synthetic resin.

4. The inlay mat as claimed in claim 1, wherein the thickness of the mat (3) is at least 1 mm.

5. The inlay mat as claimed in claim 1, wherein the underside (4) is smooth, while the top side has a height-compensating structure.

6. The inlay mat as claimed in claim 5, wherein the height-compensating structure comprises raised lamellae (6).

7. The inlay mat as claimed in claim 1, wherein the mat (3) has a sticky surface.

8. An electrical or electronic appliance (10), comprising a housing with wall parts (12, 13, 14) and electrical and/or electronic components which are arranged therein and act as a heat source, wherein a thermally conductive mat (3) as claimed in one of the preceding claims is inserted between the heat source and an adjoining wall part of the housing.

9. The appliance as claimed in claim 8, wherein at least some of the components are mounted on a circuit board (15).

10. The appliance as claimed in claim 8, wherein a film (7) with a high degree of electrical insulation is additionally inserted between mat (3) and adjoining wall part (12).

11. The appliance as claimed in claim 8, wherein the adjoining wall part, which is in particular the base plate (12), itself has good thermal conductivity and comprises in particular metal.
